(19) United States
(12) Patent Application Publication
(10) Pub. No.: US 2021/0175142 A1
(43) Pub. Date: Jun. 10, 2021

(54) INTEGRATED CIRCUIT (IC) TAG

(71) Applicant: FUJITSU LIMITED, Kawasaki-shi (JP)

(72) Inventors: Shinichi Tajima, Kawasaki (JP); Yasushi Masuda, Kawasaki (JP); Tetsuro Yamada, Kawasaki (JP); Atsushi Yamaguchi, Kawasaki (JP)

(73) Assignee: FUJITSU LIMITED, Kawasaki-shi (JP)

(21) Appl. No.: 17/080,889

(22) Filed: Oct. 27, 2020

(30) Foreign Application Priority Data
Dec. 4, 2019 (JP) 2019-219678

(51) Int. Cl. H01L 23/31; H01L 23/66; H01L 23/00

(52) U.S. Cl. CPC H01L 23/3142; H01L 24/29; H01L 23/66

(57) ABSTRACT

An integrated circuit (IC) tag includes: an IC chip; a substrate that is provided with an antenna on a first surface; an adhesive portion configured to adhere a side surface of the IC chip and a peripheral of the IC chip in a state that a terminal of the IC chip is electrically coupled to the antenna; and a first member that is provided between the antenna and the adhesive portion, the first member having an elastic modulus higher than an elastic modulus of the antenna.

### CROSS-REFERENCE TO RELATED APPLICATION

This application is based upon and claims the benefit of priority of the prior Japanese Patent Application No. 2019-219678, filed on Dec. 4, 2019, the entire contents of which are incorporated herein by reference.

### FIELD

The embodiments discussed herein are related to an integrated circuit (IC) tag.

### BACKGROUND

Conventionally, there is a circuit substrate in which a cover lay is provided on the top of copper foil wiring on the upper surface of the substrate and the upper surface of the substrate, and an IC chip is connected on the top of the cover lay via an anisotropic conductive film. A terminal of the IC chip and the wiring is electrically connected by the anisotropic conductive film.

Examples of the related art include Japanese Laid-open Patent Publication No. 2002-076059.

### SUMMARY

According to an aspect of the embodiments, an integrated circuit (IC) tag includes: an IC chip; a substrate that is provided with an antenna on a first surface; an adhesive portion configured to adhere a side surface of the IC chip and a peripheral of the IC chip in a state that a terminal of the IC chip is electrically coupled to the antenna; and a first member that is provided between the antenna and the adhesive portion, the first member having an elastic modulus higher than an elastic modulus of the antenna.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a diagram illustrating an IC tag 100 according to a first embodiment;

FIG. 2 is a diagram illustrating a cross-section taken along line A-A in FIG. 1 as viewed in the arrow direction;

FIG. 3 is a diagram illustrating a state in which a crack 130B is produced in an adhesive portion 130;

FIG. 4 is a diagram illustrating an IC tag 10 of a comparative example;

FIG. 5 is a diagram illustrating a cross-section taken along line B-B in FIG. 4;

FIG. 6 is a diagram illustrating an IC tag 200 according to a second embodiment;

FIG. 7 is a diagram illustrating a cross-section taken along line C-C in FIG. 6 as viewed in the arrow direction; and

FIG. 8 is a diagram illustrating a part of the process of manufacturing the IC tag 200 according to the second embodiment.

### DESCRIPTION OF EMBODIMENT(S)

Incidentally, IC tags are attached to various articles and are sometimes subjected to stress due to impact or the like as the articles are moved. For this reason, the IC tags are supposed to have a strong structure so as not to be damaged by stress.

In such a case, if an adhesive portion is provided between the side surface of the IC tag and the substrate to ensure the strength, the adhesive portion is made thicker, and there is a possibility that an antenna is damaged (disconnected) when a crack is produced in the adhesive portion due to impact and reaches the antenna. For example, if the antenna is damaged, the IC tag can no longer perform communication.

According to an aspect of the embodiments, provided is an IC tag capable of suppressing damage to an antenna even when used in an environment where stress is likely to be imparted.

Hereinafter, exemplary modes to which IC tags of the present embodiments are applied will be described.

### First Embodiment

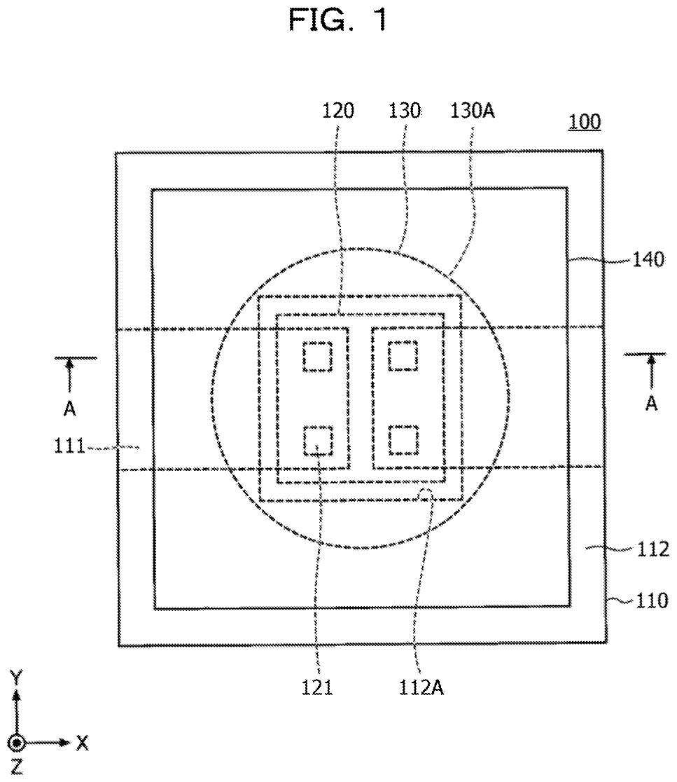

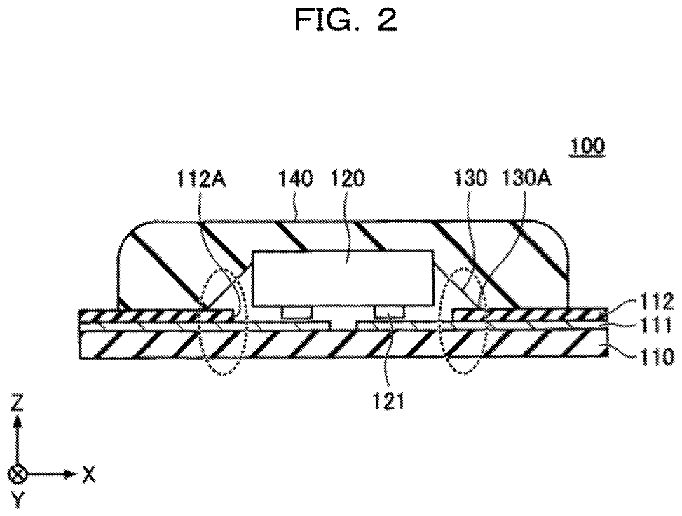

FIG. 1 is a diagram illustrating an IC tag 100 according to a first embodiment. FIG. 2 is a diagram illustrating a cross-section taken along line A-A in FIG. 1 as viewed in the arrow direction. Hereinafter, description will be given using an XYZ coordinate system. The plan view means to view in the XY plane. Furthermore, for convenience of explanation, the +Z direction side is referred to as the upper side and the −Z direction side is referred to as the lower side, but these directions do not represent a general upper-lower relationship.

The IC tag 100 is a radio frequency identifier (RFID) tag including a substrate 110, an IC chip 120, an adhesive portion 130, and a cover 140. For example, the IC tag 100 is attached to linen such as sheets or towels, and is used to identify each piece of linen. As an example, linen is washed and repeatedly used, and the washing is sometimes performed in a large industrial washing machine. When washed with such a washing machine, the linen is subjected to very large pressure, pulling force, and the like, and accordingly a very large stress is imparted to the IC tag 100 from various directions. Therefore, the IC tag 100 is expected to have a structure capable of withstanding such a very large stress.

Note that, as an example, the size of the IC chip 120 in plan view is 0.5 mm×0.5 mm, and as an example, the thickness (in the Z direction) is 0.22 mm. The dimensions of the IC tag 100 are 54 mm×5 mm in plan view, and as an example, the thickness (in the Z direction) is 0.5 mm.

The substrate 110 is made with, for example, polyethylene terephthalate (PET), and has a rectangular shape in plan view. An antenna 111 and a resist 112 are provided on an upper surface of the substrate 110. The upper surface of the substrate 110 is an example of a first surface. Although the antenna 111 is illustrated as a planar antenna as an example, the antenna 111 may be patterned in various shapes in plan view, depending on the usage of the IC tag 100, the communication frequency, and the like. The antenna 111 is implemented by, for example, a silver paste (Ag paste) applied on the upper surface of the substrate 110. The antenna 111 made with the Ag paste is softer (lower in elastic modulus) than the resist 112.

The resist 112 is formed on the top of a part of the upper surface of the substrate 110 and a part of an upper surface of the antenna 111. As the material of the resist 112, an insulating material for resist used for insulating wiring such as a wiring substrate can be used. The resist 112 is softer (lower in elastic modulus) than the thermosetting adhesive portion 130.

The resist 112 has an opening 112A having a rectangular shape at a center in plan view. An inside of the opening 112A is an area where the resist 112 is not provided. A part of the antenna 111 on a center side in the X direction is exposed at the opening 112A, The length of the opening 112A in the X direction is longer than the length of the IC chip 120 in the X direction in the cross-sectional view illustrated in FIG. 2, and is smaller than the length between two sections of a lower end 130A located on opposite sides of the adhesive portion 130 in the X direction. The lower end 130A corresponds to a position on an outermost side in plan view in an area where the adhesive portion 130 contacts the resist 112. This is because the adhesive portion 130 is inclined so as to extend outward from the upper side to the lower side in a cross-sectional view. Note that such a configuration similarly applies to a cross-section along the Y direction.

The IC chip 120 is a chip that incorporates an IC having an internal memory that stores a unique ID, and has four terminals 121 on a lower surface. The terminal 121 is electrically connected to the antenna 111 via the adhesive portion 130, and operates with the electric power received via the antenna 111 to radiate a signal that contains the ID, via the antenna 111. The signal that contains the ID is received by a reader. The IC tag 100 is a passive RFID tag that does not include a power supply.

The adhesive portion 130 is, for example, a member obtained by curing an adhesive agent that exhibits anisotropic conductivity, and adheres a part of a side surface of the IC chip 120, a part of the antenna 111, and a part of the resist 112, while having conductivity that electrically connects the terminals 121 and the antenna 111 on the lower surface of the IC chip 120.

An adhesive agent that exhibits anisotropic conductivity and implements the adhesive portion 130 is a mixture obtained by mixing conductive particles in a binder made with thermosetting resin, and when heated while pressure is imparted in the upper-lower direction (thermocompression bonding), undergoes thermosetting to adhere the terminals 121 and the antenna 111, and also to electrically connect the terminals 121 and the antenna 111 in the upper-lower direction. Furthermore, the adhesive agent that exhibits anisotropic conductivity and implements the adhesive portion 130 adheres a part of the side surface of the IC chip 120, a part of the antenna 111, and a part of the resist 112.

The lower end 130A of the adhesive portion 130 is circular in plan view, and the length between sections of the lower end 130A located on opposite sides of the adhesive portion 130 in the X direction is longer than the length of the opening 112A of the resist 112 in the X direction.

For example, the lower end 130A located at a position on the outermost side in plan view in the X direction in an area where the adhesive portion 130 contacts the resist 112 is located outside the position of an opening end of the opening 112A in plan view. Furthermore, the antenna 111 extends to the inside of the resist 112 in the X direction, and an end of the antenna 111 on the center side in the X direction is located on the lower side of the IC chip 120. Note that this similarly applies to the Y direction.

Therefore, in a peripheral portion of the IC chip 120 on the upper surface of the substrate 110, there are areas where the antenna 111, the resist 112, and the adhesive portion 130 are laminated in this order (areas indicated by two dashed ellipses in FIG. 2). Note that, the peripheral portion of the IC chip 120 denotes an area located around the IC chip 120 in a rectangular region defined by the upper surface of the substrate 110 in plan view.

The cover 140 covers the resist 112, the upper surface and an upper side part of the side surface of the IC chip 120, and the adhesive portion 130, on the upper surface of the substrate 110. The cover 140 is provided to protect the IC chip 120 and a connecting portion between the IC chip 120 and the antenna 111 from an impact or the like. The size of the cover 140 in plan view is smaller than the substrate 110 as an example, and ends of the antenna 111 on the ±X direction side and ends of the resist 112 on the ±X direction side and the ±Y direction side in plan view are not covered by the cover 140. Note that the cover 140 may be configured to cover the ends of the antenna 111 on the ±X direction side and ends of the resist 112 on the ±X direction side and ±Y direction side in plan view.

The cover 140 is a resin potting made with urethane resin, which is obtained by curing a main agent and a curing agent through chemical reaction. Since the resin potting has elasticity and is easily deformed, it is suitable for the cover of the IC tag 100 to which stress is imparted from various directions. Note that the cover 140 may be made with a material other than potting resin as long as the material has elasticity and is easily deformed.

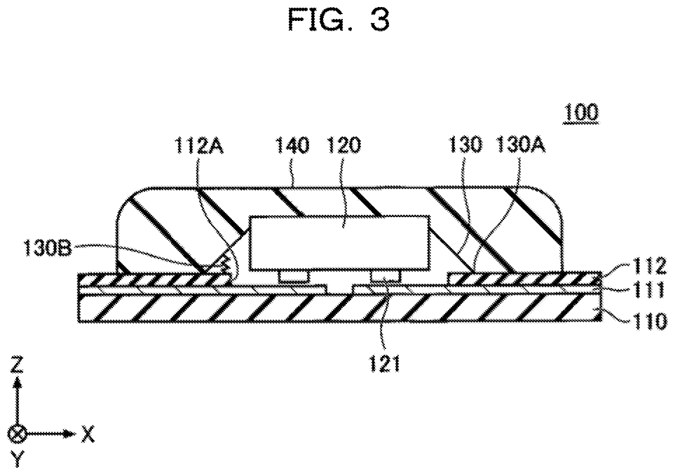

FIG. 3 is a diagram illustrating a state in which a crack 1308 is produced in the adhesive portion 130. It is assumed that stress is imparted to the IC tag 100 and a crack 130B is produced in an area of the adhesive portion 130 located on a side surface side of the IC chip 120. However, since the resist 112 that is softer and easier to deform than the adhesive portion 130 is provided between the antenna 111 and the adhesive portion 130, the crack 130B is not caused in the resist 112, and the resist 112 elastically deforms to absorb or relax the stress imparted to the adhesive portion 130; damaging the antenna 111 is thus suppressed.

In this manner, even if the crack 130B produced in an area of the adhesive portion 130 located on a side surface side (a side surface side on the X direction side) of the IC chip 120, damage to the antenna 111 may be suppressed.

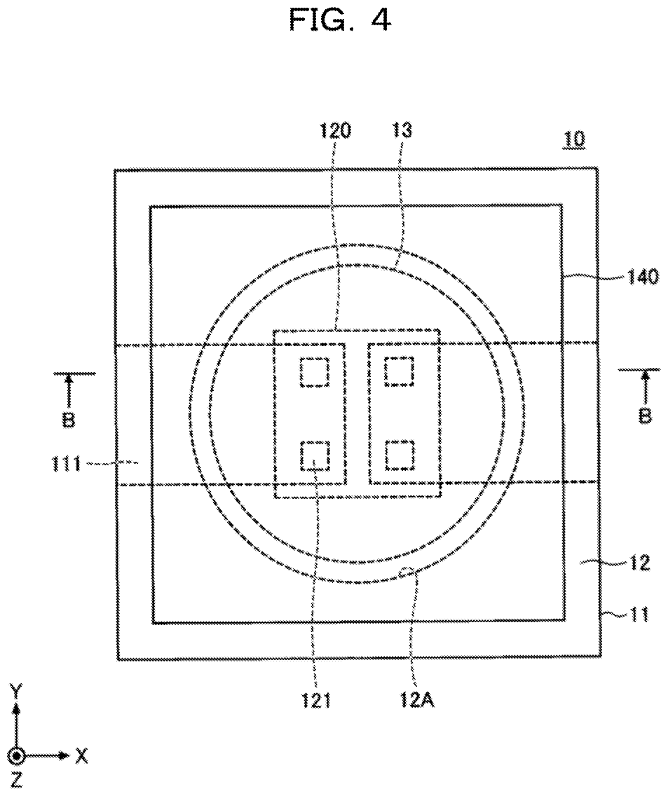

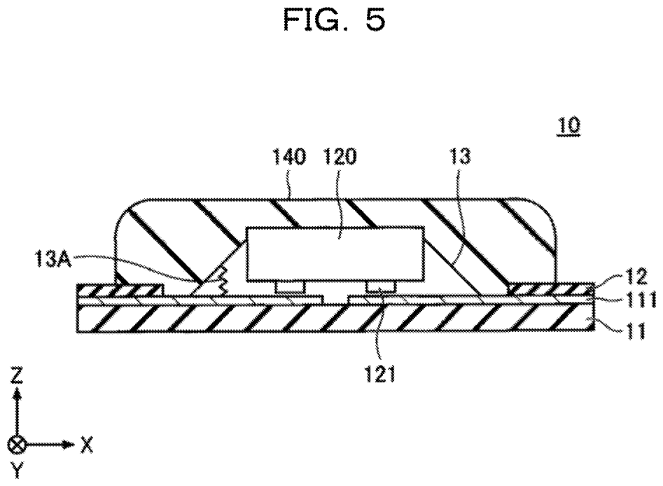

FIG. 4 is a diagram illustrating an IC tag 10 of a comparative example. FIG. 5 is a diagram illustrating a cross-section taken along line B-B in FIG. 4. Among components of the IC tag 10 of the comparative example, components similar to the components of the IC tag 100 of the first embodiment are designated by the same reference signs, and the description thereof will be omitted.

The IC tag 10 is an RFID tag including a substrate an IC chip 120, an adhesive portion 13, and a cover 140.

Similar to the substrate 110, the substrate 11 is made with PET, and has a rectangular shape in plan view. An antenna 111 and a resist 12 are provided on an upper surface of the substrate 11. The substrate 11 is different from the substrate 110 of the first embodiment in that an opening 12A of the resist 12 is larger and has a circular shape, and the resist 12 and the adhesive portion 13 have no overlapping area.

When stress is imparted to the IC tag 10, and a crack 13A is produced in an area of the adhesive portion 13 located on a side surface side (a side surface side on the X direction side) of the IC chip 120, the crack 13A reaches the antenna 111, and accordingly there is a possibility that the antenna 111 is disconnected.

In contrast to this, the IC tag 100 of the first embodiment has areas where the antenna 111, the resist 112, and the adhesive portion 130 are laminated in this order (areas indicated by two dashed ellipses in FIG. 2), in the peripheral portion of the IC chip 120 on the upper surface of the substrate 110.

Therefore, even if the crack 1308 (see FIG. 3) is produced in an area of the adhesive portion 130 located on a side surface side (a side surface side on the X direction side) of the IC chip 120, the crack 1308 reaches only the resist 112, and accordingly damage to the antenna 111 may be suppressed.

Consequently, the IC tag 100 capable of suppressing damage to the antenna 111 even when used in an environment where stress is likely to be imparted may be provided.

### Second Embodiment

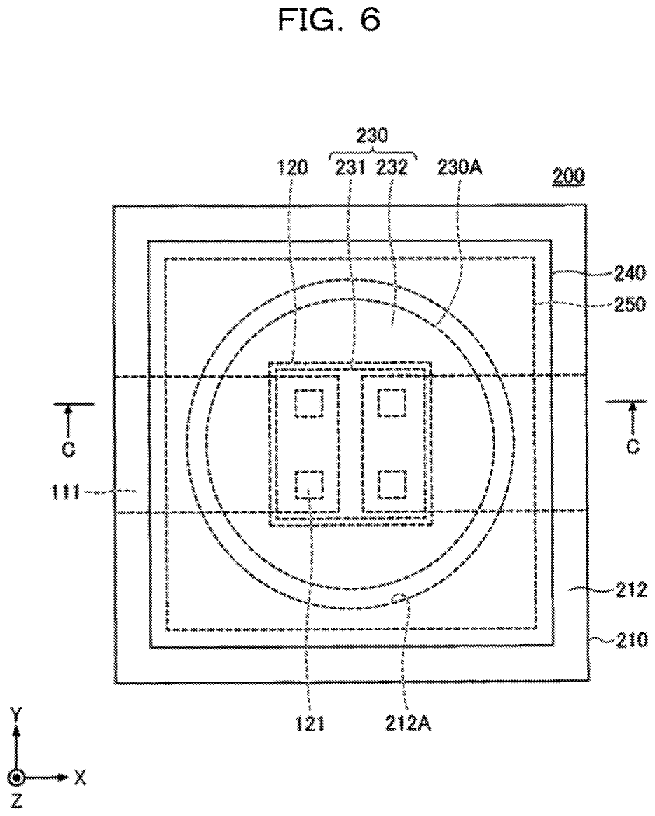

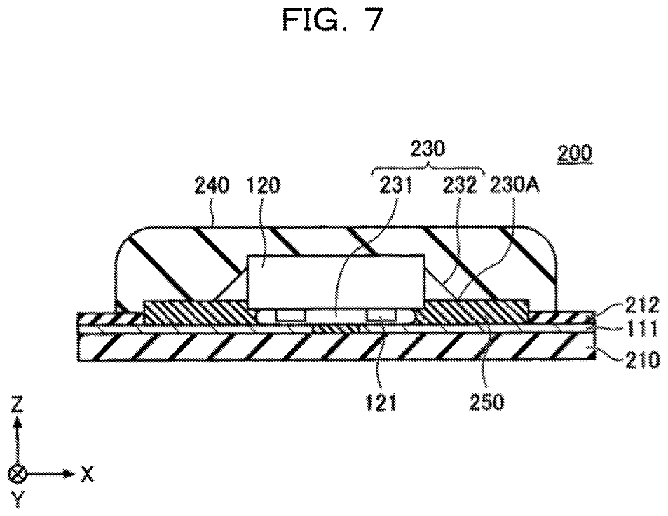

FIG. 6 is a diagram illustrating an IC tag 200 according to a second embodiment. FIG. 7 is a diagram illustrating a cross-section taken along line C-C in FIG. 6 as viewed in the arrow direction. Hereinafter, description will be given using an XYZ coordinate system. The plan view means to view in the XY plane. Furthermore, for convenience of explanation, the +Z direction side is referred to as the upper side and the −Z direction side is referred to as the lower side, but these directions do not represent a general upper-lower relationship. In addition, in the following, components similar to the components of the IC tag 100 of the first embodiment are designated by the same reference signs, and the description thereof will be omitted.

The IC tag 200 is an RFID tag including a substrate 210, an IC chip 120, an adhesive portion 230, a cover 240, and an elastic member 250. Similar to the IC tag 100 of the first embodiment, for example, the IC tag 200 is attached to linen such as sheets or towels, and is used to identify each piece of linen.

The substrate 210 is made with PET, for example, and has a rectangular shape in plan view. An antenna 111 and a resist 212 are provided on an upper surface of the substrate 210. The upper surface of the substrate 210 is an example of the first surface.

The resist 212 is formed on the top of a part of the upper surface of the substrate 210 and a part of an upper surface of the antenna 111. As the material of the resist 212, an insulating material for resist used for insulating wiring such as a wiring substrate can be used.

The resist 212 has a large opening 212A having a circular shape at a center in plan view. The opening 212A is similar to the opening 12A (see FIG. 4) of the resist 12 of the IC tag 10 of the comparative example.

The adhesive portion 230 is, for example, a member obtained by curing an adhesive agent that exhibits anisotropic conductivity, and has a connecting portion 231 and a side surface adhesive portion 232.

The connecting portion 231 adheres a lower surface of the IC chip 120 to the upper surface of the substrate 210 and the antenna 111, and also electrically connects terminals 121 of the IC chip 120 and the antenna 111. The side surface adhesive portion 232 is adhered to a side surface of the IC chip 120, and adheres the side surface of the IC chip 120 and an upper surface of the elastic member 250. An adhesive agent that exhibits anisotropic conductivity and implements the adhesive portion 230 is similar to the adhesive agent that exhibits anisotropic conductivity and implements the adhesive portion 130 of the first embodiment.

A lower end 230A of the adhesive portion 230 is circular in plan view; a circular shape formed by sections of the lower end 230A located on opposite sides of the adhesive portion 230 in the X direction is smaller than the circular shape of the opening 212A of the resist 212, and is located inside the circular shape of the opening 212A of the resist 212.

The cover 240 covers a part of the resist 212, the upper surface and an upper side part of the side surface of the IC chip 120, the side surface adhesive portion 232 of the adhesive portion 230, and a part of the elastic member 250, on the upper surface of the substrate 210. Similar to the cover 140 of the first embodiment, the cover 240 is provided to protect the antenna 111, the IC chip 120, and a connecting portion between the IC chip 120 and the antenna 111 from an impact or the like, and is implemented by similar resin potting

The elastic member 250 is provided between the antenna 111 and the side surface adhesive portion 232, and has a higher elastic modulus than the antenna 111. Since the antenna 111 made with Ag paste is softer than the resist 212 (lower in elastic modulus), the elastic member 250 is supposed to be harder than the antenna 111 and softer than the resist 212.

Making the elastic modulus of the elastic member 250 higher than the elastic modulus of the antenna 111 is to protect the antenna 111 in a case where stress to an extent to cause a crack is imparted to the side surface adhesive portion 232, by providing a member softer than the resist 212 between the side surface adhesive portion 232 and the antenna 111.

Furthermore, the elastic modulus of the elastic member 250 is an elastic modulus lower than the elastic modulus of the resist 212, or an elastic modulus that allows the terminals 121 of the IC chip 120 and an adhesive agent for the adhesive portion 230 before being thermoset to break through and penetrate the elastic member 250 when the IC chip 120 is pushed from the upper side in the course of manufacturing. Allowing the terminals 121 and the adhesive agent for the adhesive portion 230 before being thermoset to break through and penetrate the elastic member 250 means that, when the IC chip 120 placed on the adhesive agent for the adhesive portion 230 before being thermoset is pushed against the elastic member 250 to flatten and deform the elastic member 250, a hole is opened at least only in an area where the terminals 121 and the adhesive agent for the adhesive portion 230 before being thermoset overlap each other and are in touch with the elastic member 250, and an area near the hole is kept in an unified state.

In this manner, implementing the elastic modulus of the elastic member 250 as an elastic modulus that allows the terminals 121 of the IC chip 120 and the adhesive agent for the adhesive portion 230 before being thermoset to break through and penetrate the elastic member 250 when the IC chip 120 is pushed from the upper side in the course of manufacturing is enabled when the elastic modulus of the elastic member 250 is lower than the elastic modulus of the resist 212. In addition, when a resist similar to the resist 212 is used instead of the elastic member 250, the terminals 121 of the IC chip 120 and the adhesive agent for the adhesive portion 230 before being thermoset has not been allowed to break through the resist.

Therefore, the elastic modulus of the elastic member 250 is employed as an elastic modulus lower than the elastic modulus of the resist 212, or an elastic modulus that allows the terminals 121 of the IC chip 120 to break through and penetrate the elastic member 250 when the IC chip 120 is pushed from the upper side in the course of manufacturing.

As such an elastic member 250, for example, polypropylene-based resin or the like can be used.

The elastic member 250 is provided in the peripheral portion of the IC chip 120 on the upper surface of the substrate 210, between the antenna 111 and the side surface adhesive portion 232. The elastic modulus of the elastic member 250 is an elastic modulus higher than the elastic modulus of the antenna 111 and lower than the elastic modulus of the resist 212, or an elastic modulus that allows the terminals 121 of the IC chip 120 and an adhesive agent for the adhesive portion 230 before being thermoset to break through and penetrate the elastic member 250 when the IC chip 120 is pushed from the upper side in the course of manufacturing. Therefore, the elastic member 250 is easier to deform than the resist 212 and harder to deform than the antenna 111. For this reason, even if stress is imparted to the IC tag 200 and a crack is produced in the side surface adhesive portion 232, the elastic member 250 is deformed to absorb or relax the stress and protect the antenna 111, thereby being able to suppress damage to the antenna 111.

Furthermore, the elastic member 250 is in contact with the side surface of the IC chip 120. Therefore, the stress may be effectively absorbed between the side surface adhesive portion 232 and the antenna 111.

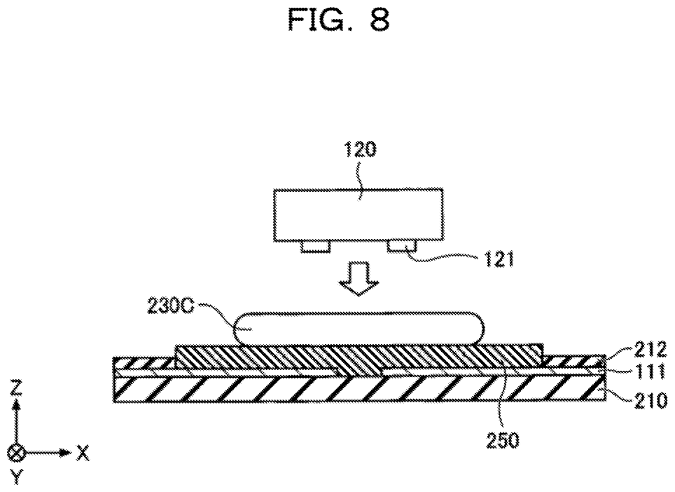

FIG. 8 is a diagram illustrating a part of the process of manufacturing the IC tag 200 according to the second embodiment. At a center portion of the upper surface of the substrate 210, the elastic member 250 and an adhesive agent 230C for the adhesive portion 230 are arranged in an overlapping manner, and when the IC chip 120 is pressed against the adhesive agent 230C in the −Z direction, the terminals 121 of the IC chip 120 and the adhesive agent 230C break through the elastic member 250 and then are positioned on the top of the antenna 111.

When the adhesive agent 230C is heated in this state, the adhesive agent 230C is separated into the connecting portion 231 and the side surface adhesive portion 232 as illustrated in FIG. 7, and the connecting portion 231 and the side surface adhesive portion 232 are cured on the lower surface and the side surface of the IC chip 120, respectively. Here, it does not matter whether a portion that connects the connecting portion 231 and the side surface adhesive portion 232 remains or no longer remains.

Since the connecting portion 231 has conductivity in the pressed direction, the terminals 121 of the IC chip 120 on the lower surface and the antenna 111 are electrically connected. Thereafter, the cover 240 can be formed.

Accordingly, even if stress is imparted to the IC tag 200 and a crack is produced in the side surface adhesive portion 232 in the adhesive portion 230, the elastic member 250 is deformed to absorb or relax the stress and protect the antenna 111, thereby being able to suppress damage to the antenna 111.

Consequently, the IC tag 200 capable of suppressing damage to the antenna even when used in an environment where stress is likely to be imparted may be provided.

Furthermore, the elastic member 250 is in contact with the side surface of the IC chip 120. Therefore, the stress may be effectively absorbed between the side surface adhesive portion 232 and the antenna 111, and even if a crack is produced in the side surface adhesive portion 232, damage to the antenna 111 may be suppressed.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An integrated circuit (IC) tag comprising:
an IC chip;
a substrate that is provided with an antenna on a first surface;
an adhesive portion configured to adhere a side surface of the IC chip and a peripheral of the IC chip in a state that a terminal of the IC chip is electrically coupled to the antenna; and
a first member that is provided between the antenna and the adhesive portion, the first member having an elastic modulus higher than an elastic modulus of the antenna.

2. The IC tag according to claim 1,
wherein the first member is a cover that has elasticity and covers the IC chip and the adhesive portion.

3. The IC tag according to claim 1,
wherein the adhesive portion includes a side surface adhesive portion and a connecting portion, the side surface adhesive portion being adhered to a side surface of the IC chip, the connecting portion being configured to adhere and also electrically couple the terminal of the IC chip and the antenna,
wherein the first member is provided between the antenna and the side surface adhesive portion in a peripheral portion of the IC chip on the first surface of the substrate, the elastic member having an elastic modulus higher than an elastic modulus of the antenna;

4. The IC tag according to claim 1,
wherein the substrate is provided with, on the first surface, the antenna and a resist, the resist having elasticity and covering at least a part of the antenna on the first surface of the substrate,
wherein the first member is formed by the resist.

5. The IC tag according to claim 2,
wherein the substrate is provided with, on the first surface, the antenna and a resist, the resist covering at least a part of the antenna on the first surface of the substrate,
wherein the resist has an opening that allows a portion of the antenna connected to the IC chip to be exposed, and
a position on an outermost side in plan view in an area where the adhesive portion contacts the resist is located outside a position of an opening end of the opening in plan view.

6. The IC tag according to claim 3,
wherein the substrate is provided with, on the first surface, the antenna and a resist, the resist covering at least a part of the antenna on the first surface of the substrate,
wherein an elastic modulus of the first member is an elastic modulus lower than an elastic modulus of the resist, or an elastic modulus that allows the terminal of the IC chip to penetrate the elastic member when the IC chip is pushed.

7. The IC tag according to claim 3,
wherein the first member is in contact with the side surface of the IC chip.

8. The IC tag according to claim 3, further comprising:
a cover that covers the IC chip, the adhesive portion, and the first member,
wherein the cover is made with potting resin.

9. The IC tag according to claim 3,
wherein the adhesive portion has a conductive filler, and is formed with an adhesive agent that exhibits anisotropic conductivity by thermocompression bonding.
